(19) United States
(12) Patent Application Publication
(10) Pub. No.: US 2026/0040847 A1
(43) Pub. Date: Feb. 5, 2026

(54) INERT RADICAL ASSISTED CVD LOW K FILM DEPOSITION

(71) Applicant: Applied Materials, Inc., Santa Clara, CA (US)

(72) Inventors: Tzu-Yu OU, San Jose, CA (US); Bo XIE, San Jose, CA (US); Chi-I LANG, Cupertino, CA (US); Li-Qun XIA, Santa Clara, CA (US); Chidambara A. RAMALINGAM, Fremont, CA (US); Shankar VENKATARAMAN, San Jose, CA (US)

(21) Appl. No.: 18/792,868

(22) Filed: Aug. 2, 2024

(51) Int. Cl. H01L 21/02; C23C 16/30; C23C 16/46; C23C 16/505; H01J 37/32

(52) U.S. Cl. CPC H01L 21/02208; C23C 16/30; C23C 16/46; C23C 16/505; H01J 37/32091; H01J 37/32357; H01J 37/32422; H01J 37/32449; H01L 21/02274; H01J 2237/3321

(57) ABSTRACT

A method for processing a substrate is provided. The method includes disposing a substrate in a processing region of a process chamber and flowing a silicon containing precursor gas into the processing region. The method also includes exposing the precursor gas to only plasma radicals and non-charged species generated from an inert gas plasma to deposit a low-k film on the substrate, wherein the low-k film comprises preserved bonds of one or more silicon containing functional groups from the one or more silicon containing precursors of the precursor gas.

### BACKGROUND

### Field

Embodiments of the present disclosure generally relate to processes for forming dielectric layers during fabrication of integrated circuits on semiconductor substrates. More specifically, embodiments described herein relate to processes for forming low-k films using radical chemical vapor deposition.

### Description of the Related Art

Current demands for faster circuitry having greater circuit densities has driven to a great degree of current research and innovation into the materials and processes implemented in the fabrication of such integrated circuits. Guided by the current trend of reducing the size of the integrated circuits, it has become beneficial to develop materials and fabrication processes that implement low dielectric materials and/or allow for the dielectric constant (k) of such films to be reduced. Current techniques for depositing low-k films, for example, plasma enabled chemical vapor deposition (PECVD) expose precursors to ions, radicals, and/or neutral species generated from a plasma to deposit the low-k film on the substrate. However, such plasma based process tends to damage the deposited films due to charged particle bombardment and high energy UV irradiation processes and generally decompose and breakdown the precursors to a level that prevents precursor structures from being preserved in the as deposited low-k film. Moreover, current materials and processes utilized to reduce the dielectric constant of such formed films often result in poor mechanical properties and performance thereof.

Thus, a need remains for the development of dielectric film materials and new fabrication methods to preserve precursor structures when producing low-k dielectric films.

### SUMMARY

In an embodiment, a method for processing a substrate is provided. The method includes disposing a substrate in a processing region of a process chamber and flowing a precursor gas into the processing region. The precursor gas includes one or more silicon containing precursors. The method also includes exposing the precursor gas to only plasma radicals and non-charged species generated from an inert gas plasma to deposit a low-k film on the substrate. The low-k film formed includes preserved bonds of one or more silicon containing functional groups from the one or more silicon containing precursors of the precursor gas.

In another embodiment, a method of processing a substrate is provided. The method includes disposing a substrate in a processing region of a process chamber, flowing an inert gas into a plasma generation region of the process chamber, and flowing a precursor gas into the processing region. The precursor gas includes one or more silicon containing precursors. The method also includes generating a remote plasma using the inert gas in the plasma generation region to form plasma ions and radicals and filtering plasma ions from the remote plasma in the plasma generation region to generate a flow of plasma radicals for introducing plasma radicals into the processing region. The flow of plasma radicals is substantially free of plasma ions. The method also includes exposing the precursor gas in the processing region to the flow of plasma radicals to form a low-k film on the substrate. The low-k film formed includes preserved bonding structures of one or more silicon containing functional groups from the silicon containing precursors of the precursor gas.

In another embodiment, a method of processing a substrate is provided. The method includes disposing a substrate in a processing region of a process chamber and flowing plasma radicals into a plasma generation region of the process chamber. The plasma radicals are generated in a remote capactively coupled plasma source in fluid communication with the plasma generation region, and the plasma radicals are generated using a radical forming gas consisting of one or more inert gases. The method also includes flowing a precursor gas into the processing region, the precursor gas comprising one or more silicon containing precursors, introducing the inert gas plasma radicals into the processing region through a showerhead adjacent to the processing region, and reacting the precursor gas in the processing region with plasma radicals to form a low-k film on the substrate. The low-k film formed includes preserved bonding structures of one or more silicon containing functional groups from the silicon containing precursors of the precursor gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber that may be used to perform the methods described herein, according to certain embodiments;

FIG. 2 is a flow chart depicting an exemplary method of forming a low-k dielectric film using the process chamber illustrated in FIG. 1, according to certain embodiments;

FIG. 3 is a graph illustrating the FTIR IR spectrum of an exemplary precursor, according to certain embodiments;

FIG. 4 is a graph illustrating the FTIR IR spectrum of a low-k film formed by the method of FIG. 2 and using the exemplary precursor of FIG. 3, according to certain embodiments;

FIG. 5 is a graph comparing the FTIR IR spectrum of FIG. 4 with a reference FTIR spectrum, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides techniques for radical based deposition of low-k films. In certain embodiments, the present disclosure provides for deposition of low-k films using radicals generated from only an inert gas, such as argon gas. In some embodiments, which may be combined with other embodiments, a plasma is generated from the inert gas to form plasma effluents (e.g., plasma ions and radicals). The plasma ions can then be filtered from the generated plasma to create a flow of plasma radicals for reacting with precursor gases to form low-k films. Techniques of the present disclosure provide for form low-k films having selected bonds or structures from the precursor preserved in the resulting deposited low-k film. Certain details are set forth in the following description and figures to provide a thorough understanding of various implementations of the disclosure. Other details describing well-known methods and systems often associated with the deposition of thin films are not set forth in the following disclosure to avoid unnecessarily obscuring the description of the various implementations.

Many of the details, components and other features described herein are merely illustrative of particular implementations. Accordingly, other implementations can have other details, components, and features without departing from the spirit or scope of the present disclosure. In addition, further implementations of the disclosure can be practiced without several of the details described below.

Other deposition chambers may also benefit from the present disclosure and the parameters disclosed herein may vary according to the particular deposition chamber used to form the dielectric film described herein. For example, other deposition chambers may have a larger or smaller volume, requiring gas flow rates that are larger or smaller than those recited for deposition chambers available from Applied Materials, Inc.

Embodiments of the present disclosure provide for deposition of low-k films, such as low-k SiOC films on substrates. While conventional processes may deposit films of similar materials, the structure and bonds of the precursors used in forming the film are typically not preserved in the resulting deposited film. For example, for SiOC films formed from direct CCP plasmas, ions from the plasma generally cleave low-k precursor structures such that the bonds and structures (i.e. CHₓ, SiH, SICH₃, SiCSi, SiO bonding) in the resulting deposited films are typically the same or very similar, as confirmed by FTIR spectrum analysis, regardless of the original bonds and structures of the precursors used.

In certain embodiments, the present disclosure utilizes a radical based chemical vapor deposition process driven by a remote plasma source formed from an inert gas only. In such embodiments, radicals generated from the remote plasma source are reacted with precursor gases to form low-k films in which increased preservation of original precursor structures and/or bonds were observed in the resulting deposited film. Without being bound by theory, it is believed that the plasma radicals generated from the inert gas have a high selectivity to cleave certain bonds of the precursors. Furthermore, when combined with tuning of processing parameters to adjust processing conditions and ion/radical ratio, certain structures and bonds of the precursors may be preserved so as to in turn affect or preserve such precursor bonds in the resulting deposited film. As the structure and bonds in the resulting deposit film directly correlate and affect the electrical and mechanical properties of the deposited film, advantages of the present disclosure provide for tuning the electrical and mechanical properties of the deposited film. In certain embodiments, the preservation of certain precursor structures and/or bonds in the deposited film provides for increased symmetry in the structures of the deposited film which in turn may provide for a lower dielectric constant (k value) and increased hardness (H).

Radical based CVD typically have the advantages of well controlled growth conditions, low thermal budget, free of defect and high quality films. In some embodiments, which may be combined with other embodiments, the radical based deposition process described herein utilizes low energy plasma radicals generated by the remote plasma source for reacting with a precursor gas to deposit the low-k film on the substrate. Due to the low energy of the plasma radicals cleaving and reacting with the precursor gas, it was observed that desired bonds of selected precursors used can be preserved in the deposited film by in part modifying processing parameters (e.g., temperature, processing pressure, spacing, RF power, flow rate etc.). As certain correlations between bond structures present and resulting film properties have been observed, tuning processing parameters so as to preserve certain precursor bonds and structures in the resulting deposited film may therefore advantageously provide for tuning one or more film properties. Embodiments of the present disclosure provide for forming low-k films with certain desired structures or bonds by using precursors with such bonds or structures, and tuning processing parameters so as to preserve the desired structures or bonds. Accordingly, methods of the present disclosure also provide for forming low-k films with tunable bond structure and film properties.

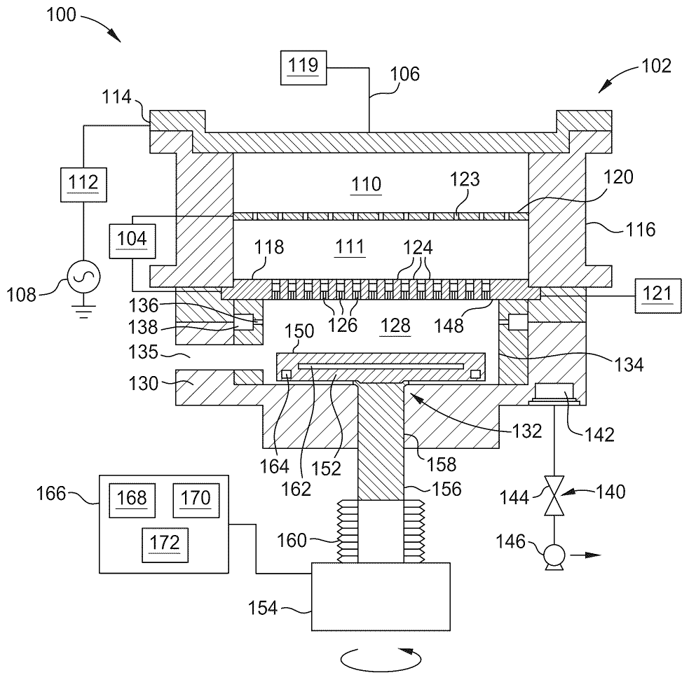

FIG. 1 is a cross-sectional view of a process chamber 100 for performing methods of the present disclosure, according to certain embodiments. In an embodiment, the process chamber 100 may be used for performing method 200 described below for forming a low-k film on a substrate.

In an embodiment, the process chamber 100 includes a lid assembly 102 having a remote plasma source. In certain embodiments, the remote plasma source may be any suitable source that is capable of generating plasma radicals from a processing gas. The remote plasma source may be a radio frequency (RF) or very high radio frequency (VHRF) capacitively coupled plasma (CCP) source, an inductively coupled plasma (ICP) source, a microwave induced (MW) plasma source, a DC glow discharge source, an electron cyclotron resonance (ECR) chamber, or a high density plasma (HDP) chamber. Alternatively, the remote plasma source may be an ultraviolet (UV) source or the filament of a hot wire chemical vapor deposition (HW-CVD) chamber.

As shown in FIG. 1, the remote plasma source comprises a plasma generation region 110 disposed between a faceplate 114 and an ion blocker 120. The faceplate 114 is part of the lid assembly 102, which also includes a lid rim 116 and a dual-channel showerhead 118. The ion blocker 120, lid rim 116, and the dual-channel showerhead 118 in turn define a remote radical region 111. The faceplate 114 includes an RF feed structure for coupling an RF power supply 108 to the faceplate 114. The RF power supply 108 is coupled to the RF feed structure via a match network 112. The RF power supply 108 is configured to apply RF power to create a differential between the faceplate 114 and the ion blocker 120 to form a capacitively coupled plasma in the plasma generation region 110.

The RF power source 108 can provide RF power at a frequency and power as appropriate for a particular application based on the processing gases used and the radical being formed. For example, the RF power source 108 may illustratively be capable of producing up to about 6000 W (but not limited to about 6000 W) at a fixed or tunable frequency in a range from about 50 kHz to about 62 MHz, such about 13.56 MHz, although other frequencies and powers may be provided as desired for particular applications. When RF current is fed to faceplate 114 via the RF feed structure from the RF power supply 108, a capactively coupled plasma can be formed inside the plasma generation region 110 from an electric field generated between the faceplate 114 and the ion blocker 120.

The plasma may be generated from a radical forming gas flowed to the plasma generation region 110 from one or more gas sources. When receiving power from the RF power source 108, the electric field energizes and ignites the radical forming gas to form the plasma. One or more radical forming gases, may enter the plasma generation region 110 via the one or more gas inlets 106. For example, the one or more gas inlets 106 may be coupled at a second end to an upstream gas source 119 of process gases that may be used to generate radicals in the plasma generation region 110 of the process chamber 100. In an embodiment, which may be combined with other embodiments, the process gases for generating the plasma radicals consists of one or more inert gases, such as argon (Ar) gas, helium (He) gas, krypton (Krypton) gas, neon (Ne) gas, or combinations thereof. In contrast to conventional methods, the resulting plasma radicals formed from such process gases and used for reacting with the precursor gas therefore excludes the use of oxygen radicals or any other oxidant radicals.

The ion blocker 120, showerhead 118, and remote radical region separate the plasma generation region 110 from a processing region 128 of the process chamber 100, and provide for the plasma generated in the plasma generation region 110 to avoid directly exciting processing gases in the processing region 128 of the process chamber 100.

In an embodiment, the ion blocker 120 has a plurality of openings 123 that allow a gas to flow from the plasma generation region 110 to the remote radical region 111. Because ions from the generated plasma are charged, the polarized ion blocker 120 acts as a barrier to ion passage through the openings 123. Since radicals are uncharged, the polarized ion blocker 120 has a minimal, if any, impact on the movement of the radicals through the openings 123 enabling radicals from the plasma generated in the plasma generation region 110 to pass through the ion blocker 210 to the remote radical region 111. In an embodiment, the ion blocker 120 generates a flow of radicals into the remote radical region 111 that is substantially free of ions. From the remote radical region 111, the flow of radicals then pass through channels in the showerhead 118 and into the processing region 128.

In some embodiments, which may be combined with other embodiments, the ion blocker 120 is polarized relative to the showerhead 128 using a voltage regulator 104. The voltage regulator 104 may configured to provide a direct current (DC) polarization of the ion blocker 120 relative to the showerhead 118 in the range of about ±2V to about ±100V, or in the range of about ±5V to about ±50V. Stated differently, the ion blocker 120 is polarized relative to the showerhead 118 in the range of about 2V to about 100V, or in the range of about 5V to about 50V, with either a positive or negative bias.

In an embodiment, which can be combined with other embodiments, radicals and neutral species from the plasma generated in the plasma generation region 110 may pass through a first plurality of channels 124 extending through the showerhead 118 to enter the processing region 128. The showerhead 118 further includes a second plurality of channels 126 that is smaller in diameter than the first plurality of channels 124. The second plurality of channels 126 connects to an internal volume (not shown) of the showerhead 118 and is not in fluid communication with the first plurality of channels 124. In an embodiment, one or more precursor gas source 121 may be coupled to the dual-channel channel showerhead 118 in fluid communication with inner volume of the showerhead 118 and the second plurality of channels 126. The precursor gas source 121 may provide a precursor gas, such as a silicon containing gas, to the dual-channel showerhead 118. The precursor gas from the precursor gas source 121 may flow through inner volume of the dual-channel showerhead 118 to the processing region 128 via the second plurality of channels 126.

Since the first plurality of channels 124 is not in fluid communication with the internal volume of the showerhead 118, the radicals passing through the first plurality of channels 124 from the remote radical region 111 are not exposed to the precursor gas flowing through the second plurality of channels 126 of the dual-channel showerhead 118. Because the showerhead 118 contains two channels that are not in fluid communication of each other, the showerhead 118 is a dual-channel showerhead 118. In certain embodiments, each of the first plurality of channels 124 has an inner diameter of about 0.10 to about 0.35 in. In certain embodiments, which can be combined with other embodiments, each of the second plurality of channels 126 has an inner diameter of about 0.01 in to about 0.04 in. In some embodiments, the dual-channel showerhead 118 may be heated or cooled. In one embodiment, which can be combined with other embodiments, the dual-channel showerhead 118 is heated to a temperature of about 100° C. to about 250° C. during processing. In another embodiment, which can be combined with other embodiments, the dual-channel showerhead 118 is cooled to a temperature of about 25° C. to about 75° C.

In addition to the ion blocker 120, the first plurality of channels 124 of the showerhead 118 may be configured to assist in suppressing the migration of ionically-charged species out of the remote radical region 111 while allowing uncharged neutral species or radicals to pass through the showerhead 118 into the processing region 128. For example, the aspect ratio of the channels 124 (i.e., the inner diameter to length) and/or the geometry of the channels 124 may be controlled so that the flow of ionically-charged species in the activated gas passing through showerhead 118 is reduced. In another example, the first plurality of channels 124 in showerhead 118 may include a tapered portion that faces the remote radical region 111, and a cylindrical portion that faces the processing region 128. The cylindrical portion may be proportioned and dimensioned to control the flow of ionic species passing into the processing region 128.

In another embodiment, which may be combined with other embodiments described herein, the ion blocker 120 may be omitted and an adjustable electrical bias may be applied to showerhead 118 as an additional means to control the flow of ionic species through showerhead 118. In some embodiments, which may be combined with other embodiments, the uncharged species and radicals may include highly reactive species that are transported with less-reactive carrier gas through the first plurality of channels 124. It is contemplated that in some examples. the uncharged species and radicals may flow through the first plurality of channels 124 without a carrier gas.

As noted above, the ion blocker 120 and showerhead 118 are configured to reduce or suppress the flow of ionic species from the generated plasma through the showerhead 118 so that only the uncharged species and/or radicals enter the process region 128 to react with the precursor gas and substrate. As it was observed that when exposed to precursors, low energy radicals exhibited preferences to selectively cleaving certain bonds of the precursors under certain processing conditions. Accordingly, by tuning processing parameters and controlling the amount of ionic species passing through showerhead 118, the methods described herein provide increased control over the reaction of the gas mixture and deposition characteristics when brought in contact with the substrate disposed in the processing region 128. For example, by limiting the makeup of the processing gas mixture in the processing region 128 to low energy radicals, processing parameters may be tuned so as to preserve certain bonds of the precursors in the deposited film so as to increase the formation of a specific network of crosslinking structures in the deposited films. Selecting precursors and tuning processing parameters to form low-k films with specific molecular structures with known correlations to film properties (e.g., k and H) in turn provides for tuning the properties of the deposited film.

The process chamber 100 may include the lid assembly 102, a chamber body 130, and a support assembly 132. The support assembly 132 may be at least partially disposed within the chamber body 130. The chamber body 130 may include a slit valve opening 135 to provide access to the interior of the process chamber 100. The chamber body 130 may include a liner 134 that covers the interior surfaces of the chamber body 130. The liner 134 may include one or more apertures 136 and a pumping channel 138 formed therein that is in fluid communication with a vacuum system 140. The apertures 136 provide a flow path for gases into the pumping channel 138, which provides an egress for the gases within the process chamber 100. Alternatively, the apertures and the pumping channel may be disposed in the bottom of the chamber body 130, and the gases may be pumped out of the process chamber 100 from the bottom of the chamber body 130.

The vacuum system 140 may include a vacuum port 142, a valve 144 and a vacuum pump 146. The vacuum pump 146 is in fluid communication with the pumping channel 138 via the vacuum port 142. The apertures 136 allow the pumping channel 138 to be in fluid communication with the processing region 128 within the chamber body 130. The processing region 128 is defined by a lower surface 148 of the dual-channel showerhead 118 and an upper surface 150 of the support assembly 132, and the processing region 128 is surrounded by the liner 134.

The support assembly 132 may include a support member 152 to support a substrate (not shown) for processing within the chamber body 130. The substrate may be any standard wafer size, such as, for example, 300 mm. Alternatively, the substrate may be larger than 300 mm, such as 450 mm or larger. The support member 152 may comprise AlN or aluminum depending on operating temperature. The support member 152 may be configured to chuck the substrate and the support member 152 may be an electrostatic chuck or a vacuum chuck.

The support member 152 may be coupled to a lift mechanism 154 through a shaft 156 which extends through a centrally-located opening 158 formed in a bottom surface of the chamber body 130. The lift mechanism 154 may be flexibly sealed to the chamber body 130 by bellows 160 that prevents vacuum leakage from around the shaft 156. The lift mechanism 154 allows the support member 152 to be moved vertically within the chamber body 130 between a process position and a lower, transfer position. The transfer position is slightly below the opening of the slit valve 135. During operation, the spacing between the substrate and the dual-channel showerhead 118 may be minimized in order to maximize radical flux at the substrate surface. For example, the spacing may be between about 100 mils and about 1,000 mils. The lift mechanism 154 may be capable of rotating the shaft 156, which in turn rotates the support member 152, causing the substrate disposed on the support member 152 to be rotated during operation. Rotation of the substrate helps improving deposition uniformity.

One or more heating elements 162 and a cooling channel 164 may be embedded in the support member 152. The heating elements 162 and cooling channel 164 may be used to control the temperature of the substrate during operation. The heating elements 162 may be any suitable heating elements, such as one or more resistive heating elements. The heating elements 162 may be connected to one or more power sources (not shown). The heating elements 162 may be controlled individually to have independent heating and/or cooling control on multi-zone heating or cooling. With the ability to have independent control on multi-zone heating and cooling, the substrate temperature profile can be enhanced at any giving process conditions. A coolant may flow through the channel 164 to cool the substrate. The support member 152 may further include gas passages extending to the upper surface 150 for flowing a cooling gas to the backside of the substrate.

The function of the process chamber 100 can be controlled by a computing device 166. The computing device 166 may be one of any form of general purpose computer that can be used in an industrial setting for controlling various chambers and sub-processors. The computing device 166 includes a computer processor 168. The computing device 166 includes memory 170. The memory 170 may include any suitable memory, such as random access memory, read only memory, flash memory, hard disk, or any other form of digital storage, local or remote. The computing device 166 may include various support circuits 172, which may be coupled to the computer processor 168 for conventionally supporting the computer processor 168. Software routines, as required, may be stored in the memory or executed by a second computing device (not shown) that is remotely located.

The computing device 166 may further include one or more computer readable media (not shown). Computer readable media generally includes any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc). In one embodiment, the memory 170 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

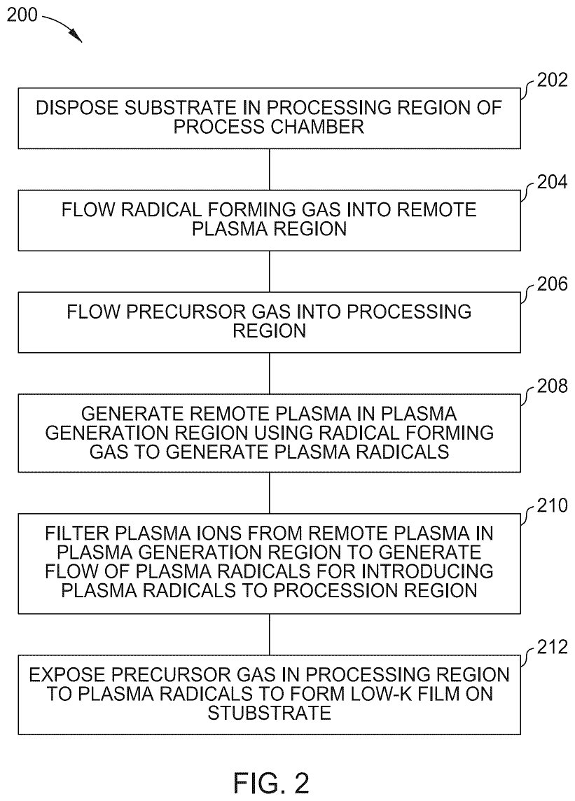

FIG. 2 depicts a flow diagram showing selected operations of a method 200 for depositing low-k films onto a substrate, according to certain embodiments. At operation 202, a substrate may be introduced to a process chamber (e.g., process chamber 100) capable of performing a chemical vapor deposition process. The substrate is positioned on a substrate support disposed in a processing region of the process chamber. The spacing (i.e., a distance between the showerhead and the substrate support) may be between about 250 mils to about 900 mils, for example about 500 mils.

At operation 204, a radical forming gas is flowed into a plasma generation region of the process chamber. In certain embodiments, the radical forming gas comprises one or more inert gases. In certain embodiments, the radical forming gas comprises an argon gas and/or helium gas.

In certain embodiments, which can be combined with other embodiments, the radical forming gas in operation 204 for forming the radicals may be flowed into the plasma generation region of the process chamber at a flow rate between about 50 sccm and about 4000 sccm, such as between about 50 sccm and about 3000 sccm, or between about 300 sccm and about 2500 sccm.

In operation 206, a precursor gas is flowed into a processing region of the process chamber. As discussed above, the processing region is separated from the plasma generation region and the remote radical region by the dual channel showerhead. The precursor gas may be flowed into the processing region through the second plurality of channels of the showerhead in fluid communication with a precursor gas source. In an embodiment, the precursor gas flowed may be selected based on the material of the low-k film desired to be deposited on the substrate. In an embodiment, the precursor gas comprises a silicon-containing gas. In an embodiment, the precursor gas flowed may be selected based on the bonds or structures desired to be preserved and present in the deposited film.

In some embodiments, the precursor gas includes a precursor containing at least one silicon-containing component, wherein a silicon atom is bonded to at least one of a carbon atom and/or an oxygen atom. In at least one embodiment, the silicon containing component may include any one or more silicon based compound, such as trimethylsilane, triethoxysilane, methyldiethoxysilane, dimethylethoxysilane, dimethylmethoxysilane, methyldimethoxysilane, dimethyldisiloxane, tetramethyldisiloxane, 1,3-bis(silanomethylene)disiloxane, bis(1-methyldisiloxanyl)methane, bis(1-methyldisiloxanyl)propane, and combinations thereof.

In some embodiments, which can be combined with other embodiments, the silicon-containing precursor gas may include, for example, dimethyldimethoxysilane (DMDMOS), methyldiethoxysilane (MDEOS), trimethylsilane (TMS), triethoxysilane, dimethylethoxysilane, dimethyldisiloxane, tetramethyldisiloxane, hexamethyldisiloxane (HMDS), 1,3-bis(silanomethylene)disiloxane, bis(1-methyldisiloxanyl)methane, bis(1-methyldisiloxanyl) propane, hexamethoxydisiloxane (HMDOS), dimethoxymethylvinylsilane (DMMVS), and combinations thereof. In some embodiments, the one or more organosilicon compounds may include one or more cyclic compounds, such as tetramethylcyclotetrasiloxane (TMCTS), octamethylcyclotetrasiloxane (OMCTS), pentamethylcyclopentasiloxane, hexamethylcyclotrisiloxane, and combinations thereof.

In one or more embodiments, which can be combined with other embodiments, the silicon-containing precursors of the precursor gas may be one of the ring-type silicon-containing precursors pictured below in molecules (I)-(III):

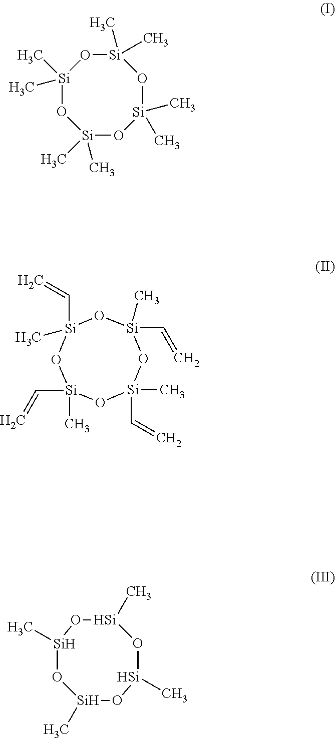

In one or more embodiments, which can be combined with other embodiments, the silicon-containing precursors of the precursor gas may be one of the linear silicon-containing precursors pictured below in molecules (IV)-(VII):

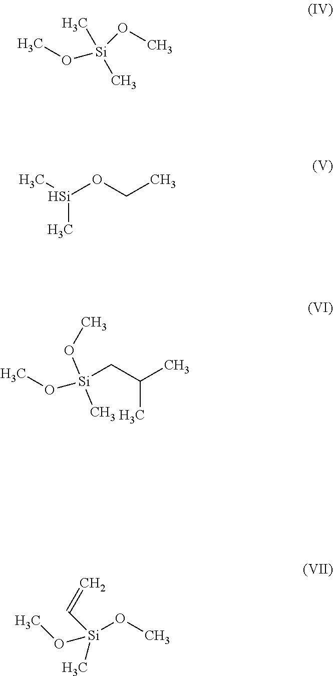

In one or more embodiments, which can be combined with other embodiments, the silicon-containing precursors of the precursor gas may be one of the Si—O—SI containing precursors pictured below in molecules (VIII) and (IX):

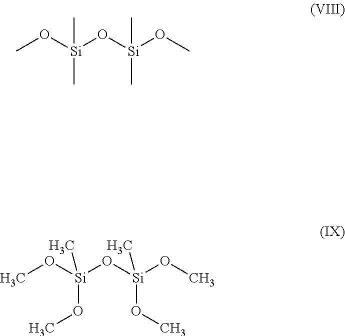

In one or more embodiments, which can be combined with other embodiments, the silicon-containing precursors of the precursor gas may be one of the Si—C—SI containing precursors pictured below in molecules (X)-(XV):

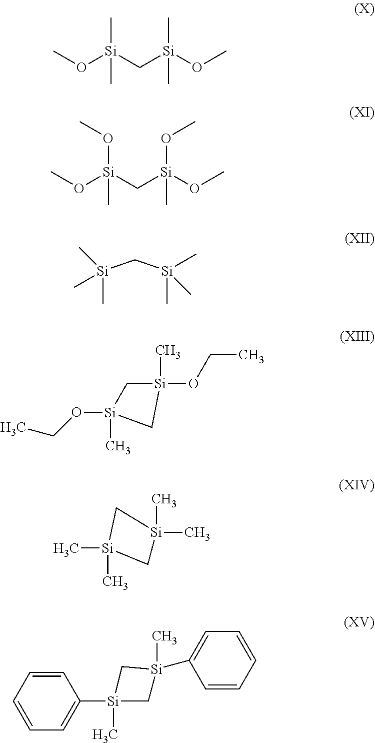

In certain embodiments, which can be combined with other embodiments, the precursor gas may further include a carrier gas, such as helium (He), argon (Ar), xenon (Xe), hydrogen (H₂), nitrogen (N₂), ammonia (NH₃), nitric oxide (NO), or any combination thereof. For example, the precursor gas may include a precursor containing at least one silicon-containing component as described above and an argon carrier gas. The flow rate of the precursor gas is between about 500 mgm and about 4000 mgm, for example about 800 mgm. The flow rate of the carrier gas may be between about 700 sccm to about 8000 sccm, for example about 2000 sccm.

The temperature of the substrate support and the substrate thereon may be maintained at a processing temperature of about 40° C. to about 400° C., such as about 250° C. The pressure of the process chamber 100 may be maintained between about 1 Torr and about 5 Torr, such as about 2.5 Torr.

In operation 208, a remote plasma is generated in the remote plasma region of the process chamber using the radical forming gas flowed in operation 204. In an embodiment, the remote plasma can be generated by any suitable technique known to the skilled artisan including, but not limited to, capactively coupled plasma, inductively coupled plasma and microwave plasma. In some embodiments, the plasma is a capacitively coupled plasma generated in the plasma generation region of process chamber 100 by applying RF and/or DC power to the faceplate to create a differential between the faceplate and one or more of the ion blocker or showerhead.

In certain embodiments, the plasma generated in the remote plasma region includes only suitable inert gases in which plasma radicals and ions are generated and the plasma radicals are used for reacting with the precursor gas in the processing region. Plasma radicals here refer to the molecules of the inert gas used excited to a metastable state. For example, when argon and helium gas is used, argon and helium ions and radicals are generated. The argon and helium ions are then filtered by the ion blocker such that only argon and helium radicals flow into the processing region for reacting with the precursor gas. In certain embodiments, radicals from the inert radical forming gas may include one or more of hydrogen radicals, nitrogen radicals, NH radicals, helium radicals, argon radicals, krypton radicals, and neon radicals. As the plasma generation region in process chamber 100 is separated from the processing region by the ion blocker and dual-channel showerhead, the generated plasma in the plasma generation region does not directly react with and excite the precursor gases flowing in the processing region of the process chamber 100. In an embodiment, the radical forming gas in the remote plasma region may be ignited into a plasma by applying RF power to the faceplate.

In an embodiment, the RF power applied in operation 208 for generating the plasma may be between about 600 Watts and about 2000 Watts, such as between about 800 Watts and about 1500 Watts, or between about 100 Watts and about 2000 Watts, or about 1800 Watts. The RF Power may be provided at a fixed or tunable frequency in a range from about 50 KHz to about 62 MHz, although other frequencies and powers may be provided as desired for particular applications. For example, the RF power may be a high frequency RF power of approximately 13.56 MHz that is capable of producing either continuous or pulsed power, although other higher or lower frequencies and powers may be provided as desired for particular applications.

In operation 210, the ion blocker is polarized to filter the plasma ions in generated plasma from the plasma radicals. Without being bound by theory, the plasma ions from the generated plasma is filtered out as it is believed that unlike radicals, the ions cleave the precursors with no selectivity. Polarizing the ion blocker decreases the ions passing through the openings in the ion blocker and generates a flow of plasma radicals from the plasma generation region into the remote radical region, wherein the flow of plasma radicals is substantially free of plasma ions. In an embodiment, the ion blocker decreases the number of ions in the generated plasma from a first number in the plasma generation region between the faceplate and the ion blocker to a second number in the remote radical region between the ion blocker and the showerhead. In some embodiments, the second number is less than or equal to about 50%, 40%, 30%, 20%, 10%, 5%, 2%, 1% or 0.5% of the first number.

In operation 212, the substrate and the precursor gas in the processing region of the process chamber 100 are exposed to the flow of plasma radicals from the remote radical region. The radicals in the processing region react with the precursor gas in the processing region to deposit a low-k film on the substrate. As discussed above, the dual-channel showerhead of the process chamber 100 may be configured to assist the ion blocker in controlling the passage of plasma effluents through the showerhead. In an embodiment, which may be combined with other embodiments, the showerhead may be configured to further reduce or completely suppress the flow of ions into the processing region. In an exemplary embodiment, the flow of radicals are introduced into the processing region through a first plurality of channels in the dual-channel showerhead. The first plurality of channels provides for the flow of radicals to enter the processing region without mixing with the precursor gas being flow into the processing region through the second plurality of channels in the showerhead.

In an embodiment, the radicals in operation 212 are supplied to the processing region until a low-k film of a desired thickness is formed on the substrate. In an embodiment, the low-k film formed comprises a low-k SiOC dielectric film. In other embodiments, the low-k dielectric film formed comprises one or more of Si, SiN, SiO, SiOCN, SiON, or SiC. The resulting low-k films deposited on the substrate can have a thickness between about 1 nm and about 600 nm, although other thicknesses are contemplated. Such a process using radicals and/or other neutral species formed from an inert gas can advantageously also reduce plasma damage compared to conventional PECVD processes that include ion bombardment of growing films. Moreover, low-k films deposited according to the methods disclosed herein can lower cost as compared to conventional radical CVD techniques using more than one processing gas to form radicals, such as a combination of oxygen and argon gas.

While FIG. 2 illustrates one example of a flow diagram, it is to be noted that variations of method 200 are contemplated. For example, it is contemplated that operation 206 may occur prior to operation 204. Additionally, it is contemplated that one or more of operations 204-210 may occur concurrently.

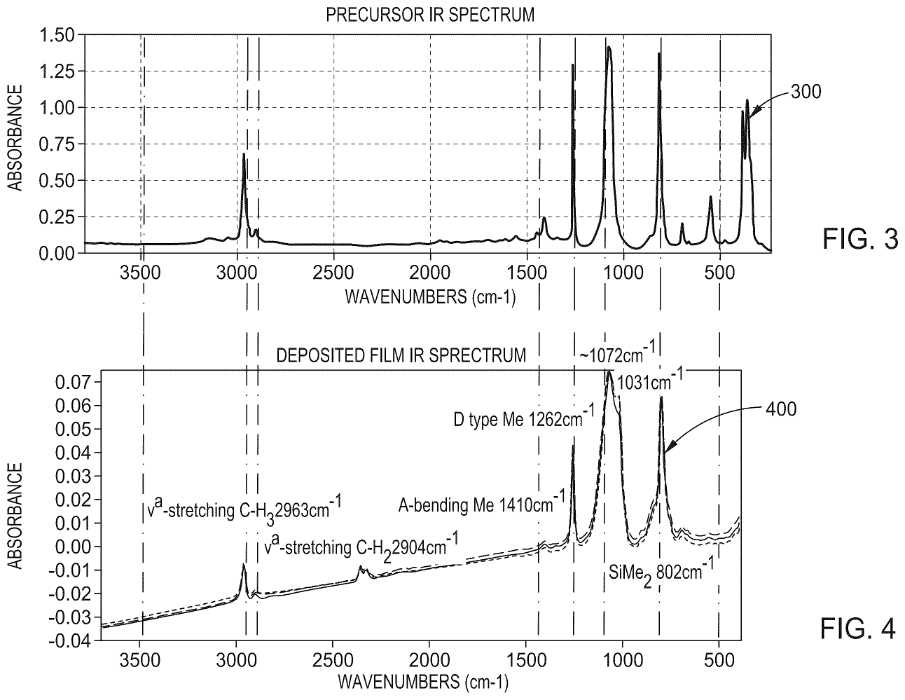

FIG. 3 shows a graph illustrating an IR spectrum 300 of an octamethylcyclotetrasiloxane (OMCTS) precusor molecule, according to certain embodiments. FIG. 4 shows a graph illustrating an IR spectrum 400 corresponding to a SiOC film formed using OMCTS precursors, according to certain embodiments. In the example of FIG. 4, the SiOC film that IR spectrum 400 corresponds to is a film deposited by reacting OMCTS precursors with radicals generated from pure argon gas plasma. The alignment of IR absorbance peaks between IR spectrums 300 and 400 in the graphs of FIGS. 3 and 4 indicate that certain bonds and structures of the OMCTS precursor present (as indicated by peaks in IR spectrum 300) are preserved when OMCTS is reacted with radicals in a radical CVD process formed from pure Ar gas. For example, absorbance peaks at 1262 cm⁻¹ and 802 cm⁻¹ frequencies corresponding to D-type Me and SiMe₂ groups, respectively, were present in both graphs. Furthermore, it was also observed that absorbance peaks corresponding to Si—O—Si functional groups indicated such bonds were more linear and networked in the deposited SiOC film. C-H₂ peaks at a frequency of about 2904 cm⁻¹ indicating linkage between OMCTS molecules were also detected in the deposited SiOC film.

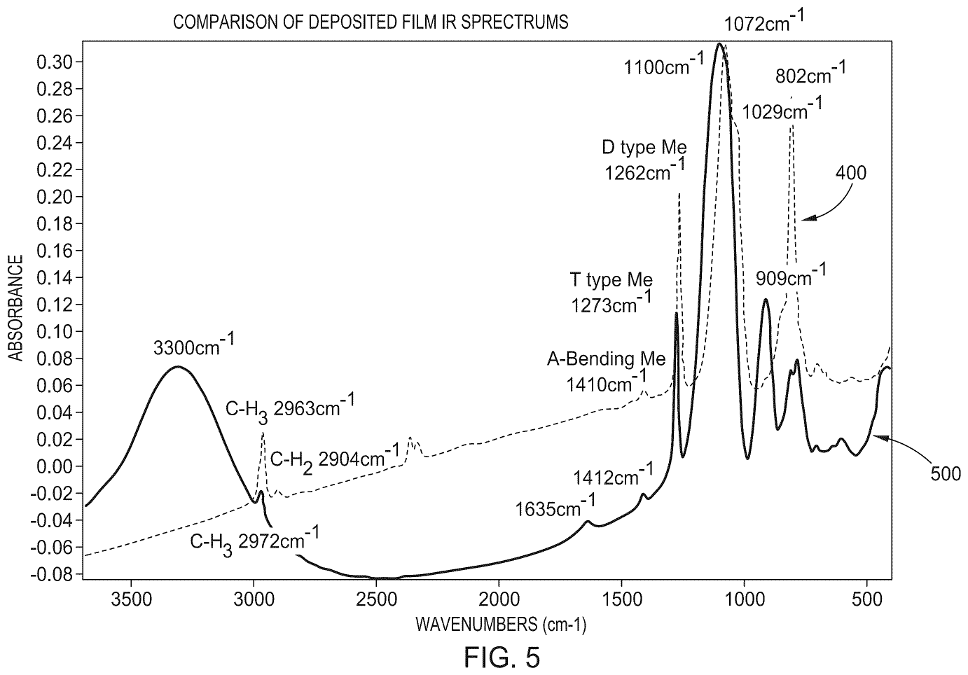

FIG. 5 is a graph comparing IR spectrum 400 of FIG. 4 with an IR spectrum 500 for a SiOC film deposited by reacting OMCTS precursors with radicals generated from an Ar and O₂ gas mixture plasma. Specifically, FIG. 5 shows IR spectrums 400 and 500 overlaid over one another. As compared with IR spectrum 500, IR spectrum 400 shows more linear/networked Si—O—Si functional groups, clearer SiMe₂ groups at around 800 cm⁻¹ frequencies, D-type Me functional groups at about 1262 cm⁻¹ frequency peaks, peaks for both C—H₂ and C—H₃ functional groups, and lack of 3300 cm⁻¹ frequency peaks corresponding to Si—OH functional groups. In contrast, the IR spectrum 500 shows T-type Me groups at about 1273 c⁻¹ frequencies instead of D-type Me functional groups, peaks for only C—H₃ functional groups, and peaks for Si—OH functional groups. The foregoing indicates radicals generated from an inert gas such as pure Ar gas react with and cleave the same precursors differently as compared to radicals generated from a mixture of an inert gas and an oxidant, such as Ar and O₂ gas.

Table 1 compares properties of SiOC films formed using the methods disclosed herein at different processing temperatures, according to certain embodiments. Due to the low energy of the plasma radicals cracking and reacting with the precursor gas to form the dielectric film, it was observed that desired bonds and chemical structures of the deposited film could be preserved by modifying one or more processing parameters. In an embodiment, low-k SiOC film were formed by reacting dimethyldimethoxysilane (DMDMOS) precursors with radicals generated from pure Ar gas plasma at 400° C. and 250° C. For comparison, films formed using direct CCP generated from the same DMDMOS precursors are also provided as reference. As shown Table 1, modification of processing temperature provides for tuning the bond configurations of the deposited film, such as providing for strong Si—O crosslinking and comparable Si—C—Si bonding, both of which assist in further increasing hardness. In an embodiment, which may be combined with other embodiments herein, modifying processing temperature is one of the parameters for tuning the hardness of the as deposited film. Specifically, in an embodiment, film deposited at 400° C. exhibited a much higher hardness than when formed at lower temperatures. In an embodiment, varying processing temperature may provide for tuning Si—CH₃, Si—C—Si, and/or C—H bonds in the resulting deposited low-k film.

TABLE 1

| | | Film 1 | Film 2 | Ref 1 | Ref 2 |
|---|---|---|---|---|---|
| Processing Condition | | Ar gas only | Ar gas only | Direct CCP | Direct CCP |
| | | radicals | radicals | | |
| Precursor | | DMDMOS | DMDMOS | DMDMOS | DMDMOS |
| RF Power (13.56 MHz) | | 1800 W | 1800 W | 600 W | 600 W |
| k | | 3.61 | 2.78 | 3.17 | 2.54 |
| Temperature (° C.) | | 400 | 250 | 400 | 260 |
| Hardness (H) | | 12.06 | 4.29 | 4.96 | 1.88 |
| FTIR | CHx | 2.31 | 3.39 | 2.8 | 2.69 |
| Functional | Si—C—Si | 36.81 | 15.96 | 34.2 | 17.83 |
| Groups | SIH | 26.05 | 20.52 | 17.5 | 12.56 |
| (Intensity/Å) | Me | 14.1 | 35 | 37.8 | 50.5 |
| | Si—O | 135 | 140.3 | 178.4 | 144.3 |

Table 2 compares properties of films formed using the methods disclosed herein at 250° C. at different processing pressures, according to certain embodiments. In an embodiment, low-k films were formed at 0.9 Torr processing pressure, 2 Torr processing pressure, and 2.5 Torr processing pressure. As shown in Table 2,modification of processing pressures also provides for tuning the bond configurations of the deposited film, according to certain embodiments. As decreasing processing pressure generally increases radical ion energy, doing so can be used to tune film property, such as to increase both k and hardness. In an embodiment, processing at low pressure indicated a tendency to form strong network structures comprising of Si—O and Si—C crosslinking. The modification of processing pressure also provides for tuning the hardness of the as deposited film. Specifically, film deposited at lower pressures exhibited a much higher hardness (H) and modulus (E) than when formed at higher pressures.

TABLE 2

| | | Film 1 | Film 2 | Film 1 |
|---|---|---|---|---|
| Processing Condition | | Ar gas only | Ar gas only | Ar gas only |
| | | radicals | radicals | radicals |
| Precursor | | DMDMOS | DMDMOS | DMDMOS |
| Pressure | | 2.5 | 2 | 0.9 |
| k | | 2.85 | 2.78 | 3.10/3.21 |
| Temperature (° C.) | | 250 | 250 | 250 |
| Modulus (E) | | 18.36 | 23.44 | 41.54 |
| Hardness (H) | | 3.27 | 4.29 | 7.13 |
| Conformality (Å) | | 7.9 | 6.5 | 29.6 |
| Ave DR | | 47 | 46 | 29 |
| FTIR | C—H | 3.39 | 3.39 | 3.48 |
| Functional | Si—H | 36.81 | 15.96 | 34.2 |
| Group | Si—C—Si | 11.77 | 15.96 | 15.99 |
| Analysis | SiCH₃ | 39.5 | 35 | 29.6 |
| (Intensity/Å) | Si—O | 154.6 | 140.3 | 126.1 |
| SiCSi/SiO | | .076 | .114 | .127 |

Accordingly, during deposition of low-k films using the methods disclosed herein, parameters such as processing temperature, processing pressure, RF power, and flow rate of processes gases (radical forming and precursor gases) may be adjusted to tune the molecular structures and properties of the deposited low-k film.

The methods and apparatuses disclosed herein enables preserving certain structural bonds of precursors in the deposited which in turn provides for the fine-tuning of the properties of deposited low-k film. By selecting precursors with desirable bonding structures, reacting the precursors with inert gas radicals from a remote plasma generated using only an inert gas, and tuning processing parameters during formation of the radicals and/or deposition of the low-k film, the present disclosure provides for selectively preserving certain bond structures in the resulting low-k film so as to tune corresponding mechanical properties of the film. In general, deposition process parameters and process times may be adjusted to tune the bonding structure, chemical composition, composition ratio, electrical properties (dielectric constant), and/or mechanical properties (e.g., hardness (H) and Young's modulus (E)) of the deposited film. The reaction gas flow rate, precursor gas flow rate, radical generation RF power, processing pressure, radical density, and substrate temperature are examples of adjustable process parameters. The process parameters can be adjusted alone or in combination with the process time. Accordingly, by using radicals generated from an inert gas plasma and fine tuning the above-noted parameters during radical generation and/or film deposition, low-k films with preserved precursor bonding structures and tunable mechanical properties may be formed.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A method for processing a substrate, comprising:
disposing a substrate in a processing region of a process chamber;
flowing a precursor gas into the processing region, the precursor gas comprising one or more silicon containing precursors; and
exposing the precursor gas to plasma to deposit a low-k film on the substrate, wherein the plasma radicals are generated from a remote plasma formed from a radical forming gas consisting of one or more inert gases, and the low-k film comprises preserved bonds of one or more silicon containing functional groups from the one or more silicon containing precursors of the precursor gas.

2. The method of claim 1, further comprising flowing a carrier gas into the processing region, wherein the carrier gas comprises an inert gas.

3. The method of claim 1, wherein plasma radicals are generated in a remote capactively coupled plasma source using a radical forming gas consisting of an inert gas.

4. The method of claim 1, wherein exposing the precursor gas to inert gas plasma radicals comprises flowing plasma radicals into the processing region through a showerhead adjacent to the processing region of the process chamber.

5. The method of claim 1, further comprising heating the substrate support with the substrate thereon to a processing temperature of about 40° C. to about 400° C.

6. The method of claim 1, wherein a pressure in the process chamber during the exposing the precursor gas to only plasma radicals is about 1.0 Torr to about 5.0 Torr.

7. The method of claim 1, wherein the one or more silicon containing precursors is flowed to the processing region at a flow rate of about 500 mgm to about 4000 mgm.

8. The method of claim 2, wherein the carrier gas is flowed to the processing region at a flow rate of about 700 sccm to about 8000 sccm.

9. The method of claim 1, wherein the low-k film lacks Si—OH functional groups.

10. The method of claim 1, wherein at least one of the one or more silicon containing precursors comprises D-type Me functional groups, and wherein the low-k film comprises D-type Me functional groups as preserved bonds of one or more silicon containing functional groups from the one or more silicon containing precursors of the precursor gas.

11. The method of claim 1, wherein the precursor gas comprises a ring-type silicon-containing precursor selected from a group consisting of:

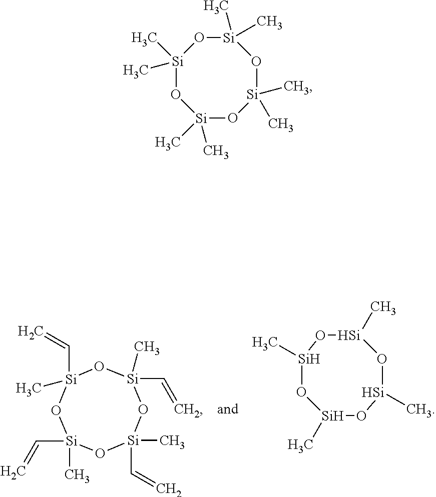

12. The method of claim 1, wherein the precursor gas comprises a linear silicon-containing precursor selected from a group consisting of:

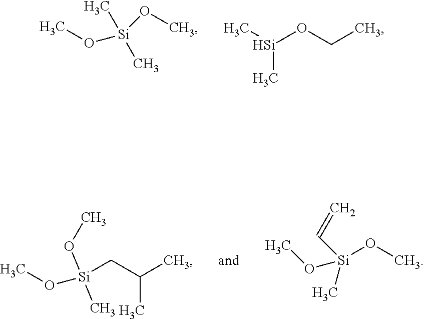

13. The method of claim 1, wherein the precursor gas comprises a Si—C—SI containing precursor selected from a group consisting of:

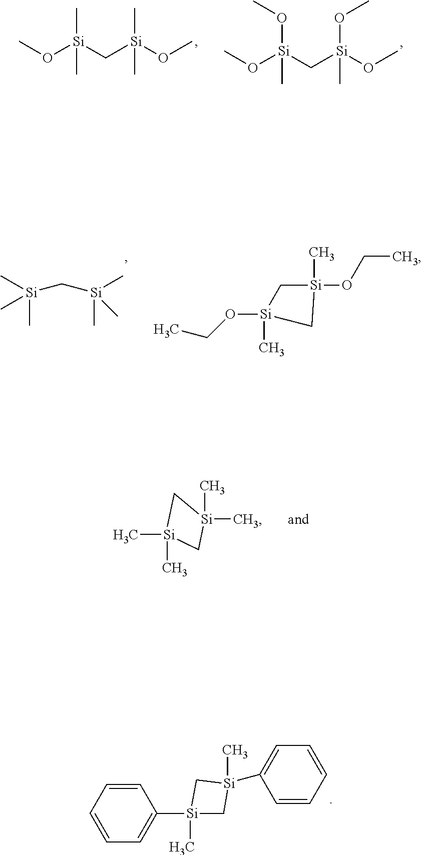

14. A method for processing a substrate, comprising:
disposing a substrate in a processing region of a process chamber;
flowing a radical forming gas consisting of one or more inert gases into a plasma generation region of the process chamber;
flowing a precursor gas into the processing region, the precursor gas comprising one or more silicon containing precursors;
generating a remote plasma using the radical forming gas in the plasma generation region to form plasma ions and plasma radicals;
filtering plasma ions from the remote plasma in the plasma generation region to generate a flow of plasma radicals for introducing plasma radicals into the processing region, wherein the flow of plasma radicals is substantially free of plasma ions; and
exposing the precursor gas in the processing region to the flow of plasma radicals to form a low-k film on the substrate, wherein the low-k film comprises preserved bonding structures of one or more silicon containing functional groups from the silicon containing precursors of the precursor gas.

15. The method of claim 14, wherein filtering plasma ions comprises polarizing an ion blocker in the plasma generation region to suppress flow of plasma ions through the ion blocker.

16. The method of claim 14, wherein exposing the precursor gas to the flow of plasma radicals comprises introducing the flow of plasma radicals to the processing region through a second plurality of channels in a showerhead adjacent to and spaced from the ion blocker.

17. The method of claim 14, wherein the precursor gas is flowed into the processing region through a second plurality of channels in a showerhead partially defining the processing region.

18. The method of claim 14, wherein at least one of the one or more silicon containing precursors comprises D-type Me functional groups, and wherein the low-k film comprises D-type Me functional groups as preserved bonds of one or more silicon containing functional groups from the one or more silicon containing precursors of the precursor gas.

19. A method for processing a substrate, comprising:
disposing a substrate in a processing region of a process chamber;
flowing plasma radicals into a plasma generation region of the process chamber, wherein the plasma radicals are generated in a remote capactively coupled plasma source in fluid communication with the plasma generation region, and the plasma radicals are generated using a radical forming gas consisting of one or more inert gases;
flowing a precursor gas into the processing region, the precursor gas comprising one or more silicon containing precursors;
introducing the inert gas plasma radicals into the processing region through a showerhead adjacent to the processing region; and
reacting the precursor gas in the processing region with plasma radicals to form a low-k film on the substrate, wherein the low-k film comprises preserved bonding structures of one or more silicon containing functional groups from the silicon containing precursors of the precursor gas.

20. The method of claim 19, wherein at least one of the one or more silicon containing precursors comprises D-type Me functional groups, and wherein the low-k film comprises D-type Me functional groups as preserved bonds of one or more silicon containing functional groups from the one or more silicon containing precursors of the precursor gas.
